(19) United States
(12) Patent Application Publication
(10) Pub. No.: US 2013/0220804 A1
(43) Pub. Date: Aug. 29, 2013

(54) Ferromagnetic Material Sputtering Target

(71) Applicants: Atsutoshi Arakawa, Ibaraki (JP); Yuki Ikeda, Ibaraki (JP)

(72) Inventors: Atsutoshi Arakawa, Ibaraki (JP); Yuki Ikeda, Ibaraki (JP)

(73) Assignee: JX NIPPON MINING & METALS CORPORATION, Tokyo (JP)

(21) Appl. No.: 13/877,411

(22) PCT Filed: Dec. 6, 2011
(86) PCT No.: PCT/JP2011/078152

§ 371 Date: Apr. 2, 2013

(30) Foreign Application Priority Data
Dec. 9, 2010 (JP) 2010-274607

(51) Int. Cl. C23C 14/34

(52) U.S. Cl. CPC C23C 14/3414
USPC 204/298.13

(57) ABSTRACT

Provided is a ferromagnetic material sputtering target having a metal composition comprising 5 mol % or more of Pt and the balance of Co, wherein the target has a structure including a metal base (A) and a phase (B) of a Co—Pt alloy containing 40 to 76 mol % of Pt in the metal base (A). Further provided is a ferromagnetic material sputtering target having a metal composition comprising 5 mol % or more of Pt, 20 mol % or less of Cr, and the balance of Co, wherein the target has a structure including a metal base (A) and a phase (B) of a Co—Pt alloy containing 40 to 76 mol % of Pt in the metal base (A). The present invention provides a ferromagnetic material sputtering target that can improve the leakage magnetic flux to allow stable discharge with a magnetron sputtering device.

### BACKGROUND

The present invention relates to a ferromagnetic material sputtering target that is used for forming a magnetic thin film of a magnetic recording medium, in particular, a magnetic recording layer of a hard disk employing a perpendicular magnetic recording system, and relates to a nonmagnetic material particle-dispersed ferromagnetic material sputtering target that provides a large leakage magnetic flux and can provide stable electric discharge in sputtering with a magnetron sputtering apparatus.

In the field of magnetic recording represented by hard disk drives, ferromagnetic metal materials, i.e. Co, Fe, or Ni-based materials are used as materials of magnetic thin films that perform recording. For example, Co—Cr-based or Co—Cr—Pt-based ferromagnetic alloys with Co as its main component are used for recording layers of hard disks employing a longitudinal magnetic recording system.

In recording layers of hard disks employing a perpendicular magnetic recording system that has been recently applied to practical use, composite materials each composed of a Co—Cr—Pt-based ferromagnetic alloy of which main component is Co and a nonmagnetic inorganic material are widely used.

In many cases, the magnetic thin film of a magnetic recording medium such as a hard disk is produced by sputtering a ferromagnetic material sputtering target of which main component is the above-mentioned material because of its high productivity.

Such a ferromagnetic material sputtering target can be produced by a melting process or a powder metallurgical process. Though which process is used depends on the requirement in characteristics and is a hard one to define, the sputtering target composed of a ferromagnetic alloy and nonmagnetic inorganic particles, which is used for a recording layer of a hard disk of a perpendicular magnetic recording system, is generally produced by a powder metallurgical process. This is because it is difficult to produce the sputtering target by a melting process, since inorganic particles need to be uniformly dispersed in an alloy base.

For example, proposed is a method of preparing a sputtering target for magnetic recording media by mechanically alloying an alloy powder having an alloy phase produced by rapid solidification and a powder constituting a ceramic phase, uniformly dispersing the powder constituting a ceramic phase in the alloy powder, and molding the dispersion with a hot press (Patent Literature 1).

The target structure in this case appears such that the base links in a soft cod roe-like manner and SiO₂ (ceramics) surrounds the base (FIG. 2 of Patent Literature 1) or is dispersed in the form of thin strings in the base (FIG. 3 of Patent Literature 1). Though other drawings are unclear, they look like to have similar structures.

Unfortunately, such a structure has problems described below and is not a preferred sputtering target for magnetic recording media. Note that the spherical material shown in FIG. 4 of Patent Literature 1 is not a structure constituting the target but a mechanically alloyed powder.

A ferromagnetic material sputtering target also can be produced without using an alloy powder produced by rapid solidification as in the following way. Prepare and weigh commercially available raw material powders as the components constituting a target so as to give a desired composition, mix the powders by a known process with a ball mill, for example, and mold and sinter the powder mixture with a hot press.

For example, proposed is a method of preparing a sputtering target for magnetic recording media by mixing a Co powder, a Co—Cr alloy powder, a Pt powder, and a SiO₂ powder as raw materials with a ball mill and molding the resulting powder mixture with a hot press (Patent Literature 2).

The target structure in this case appears such that a metal phase (B) of a Co—Cr alloy is present in a metal base (A) in which inorganic particles are uniformly dispersed (FIG. 11 of Patent Literature 2). Though such a structure is suitable for a target containing Cr to some extent or more (e.g., Cr: 10 mol % or more), the recording medium characteristics as a sputtering target for magnetic recording media are inferior compared with those of a target composition having a low content of Cr (e.g., Cr: 5 mol % or less), and the structure is not necessarily preferred.

Furthermore, proposed is a method of preparing a sputtering target for forming magnetic recording medium thin films by mixing a Co—Cr binary alloy powder, a Pt powder, and a SiO₂ powder and hot-pressing the resulting powder mixture (Patent Literature 3).

It is described that the target structure in this case has a Pt phase, a SiO₂ phase, and a Co—Cr binary alloy phase and that a dispersion layer is observed in the periphery of the Co—Cr binary alloy layer (not shown in drawing). A structure not having dispersion of such an oxide is also not preferred as a sputtering target for magnetic recording media.

There are sputtering apparatuses of various systems. In formation of the magnetic recording films, magnetron sputtering devices equipped with DC power sources are widely used because of their high productivity. Sputtering is a method of generating an electric field by applying a high voltage between a substrate serving as a positive electrode and a target serving as a negative electrode disposed so as to face each other under an inert gas atmosphere.

On this occasion, the inert gas is ionized into plasma composed of electrons and cations. The cations in the plasma collide with the surface of the target (negative electrode) to make the target constituent atoms fly out from the target and to allow the flying out atoms to adhere to the facing substrate surface so that a film is formed. Sputtering is based on the principle that a film of the material constituting a target is formed on a substrate by such a series of actions.
Patent Literature 1: Japanese Patent Laid-Open Publication No. H10-88333
Patent Literature 2: Japanese Patent No. 4499183
Patent Literature 3: Japanese Patent Laid-Open Publication No. 2009-1860

### SUMMARY OF THE INVENTION

### Technical Problem

In general, in sputtering of a ferromagnetic material sputtering target with a magnetron sputtering device, most of the magnetic flux from a magnet passes through the inside of the target made of a ferromagnetic material to reduce the leakage magnetic flux, resulting in a big problem of no discharge or unstable discharge in sputtering.

In order to solve this problem, a reduction in content of Co as a ferromagnetic metal is suggested. A reduction in Co content, however, does not allow formation of a desired magnetic recording film and is therefore not an essential solution. It is possible to increase the leakage magnetic flux by reducing the thickness of the target, however, in this case, the target lifetime is shortened to require frequent replacement of the target, which causes an increase in the cost.

In view of the problems mentioned above, it is an object of the present invention to provide a nonmagnetic material particle-dispersed ferromagnetic material sputtering target that increases the leakage magnetic flux to allow stable discharge with a magnetron sputtering device.

### Solution to Problem

In order to solve the above-mentioned problems, the present inventors have performed diligent studies and, as a result, have found that a target providing a large leakage magnetic flux can be obtained by regulating the composition and structural constitution of the target.

Based on the findings, the present invention provides:

1) a ferromagnetic material sputtering target having a metal composition comprising 5 mol % or more of Pt and the balance of Co, wherein the target has a structure including a metal base (A) and a phase (B) of a Co—Pt alloy containing 40 to 76 mol % of Pt in the metal base (A).

The present invention further provides:

2) a ferromagnetic material sputtering target having a metal composition comprising 5 mol % or more of Pt, 20 mol % or less of Cr, and the balance of Co, wherein the target has a structure including a metal base (A) and a phase (B) of a Co—Pt alloy containing 40 to 76 mol % of Pt in the metal base (A).

The present invention further provides:

3) the ferromagnetic material sputtering target according to 1) or 2) above, further comprising 0.5 mol % or more and 10 mol % or less of at least one element selected from B, Ti, V, Mn, Zr, Nb, Ru, Mo, Ta, W, Si, and Al as additional elements.

The present invention further provides:

4) the ferromagnetic material sputtering target according to any one of 1) to 3) above, wherein the metal base (A) contains at least one inorganic material component selected from carbon, oxides, nitrides, carbides, and carbonitrides in the metal base.

The present invention further provides:

5) the ferromagnetic material sputtering target according to 4) above, wherein the inorganic material is at least one oxide of an element selected from Cr, Ta, Si, Ti, Zr, Al, Nb, B, and Co; and the volume proportion of the inorganic material is 22 to 40 vol %.

The present invention further provides:

6) the ferromagnetic material sputtering target according to any one of 1) to 5) above, wherein the phase (B) of a Co—Pt alloy has a particle diameter of 10 μm or more and 150 μm or less.

The present invention further provides:

7) the ferromagnetic material sputtering target according to any one of 1) to 6) above, having a relative density of 97% or more.

### Effects of Invention

The nonmagnetic material particle-dispersed ferromagnetic material sputtering target thus prepared of the present invention provides a large leakage magnetic flux to allow efficiently accelerated ionization of an inert gas to give stable discharge when used in a magnetron sputtering device. It is possible to increase the thickness of the target to enable a reduction in frequency of replacement of the target, resulting in an advantage that a magnetic thin film can be produced with low cost.

### BRIEF DESCRIPTION OF DRAWINGS

FIG. 1 is a structural image of a polished surface of a target of Example 1 under an optical microscope.

FIG. 2 is a structural image of a polished surface of a target of Comparative Example 1 under an optical microscope.

FIG. 3 is a structural image of a polished surface of a target of Example 2 under an optical microscope.

FIG. 4 is a structural image of a polished surface of a target of Comparative Example 2 under an optical microscope.

FIG. 5 is a structural image of a polished surface of a target of Comparative Example 3 under an optical microscope.

FIG. 6 is a structural image of a polished surface of a target of Comparative Example 4 under an optical microscope.

### DETAILED DESCRIPTION OF THE INVENTION

The main component constituting a ferromagnetic material sputtering target of the present invention is a metal composition comprising 5 mol % or more of Pt and the balance of Co.

Though these metals are indispensable components in a magnetic recording medium, the Pt content is desirably 45 mol % or less. An excessive amount of Pt decreases the characteristics as a magnetic material. In addition, since Pt is expensive, a smaller amount of Pt is desirable from the viewpoint of manufacturing cost.

The ferromagnetic material sputtering target of the present invention may further comprise 20 mol % or less of Cr and/or 0.5 mol % or more and 10 mol % or less of at least one element selected from B, Ti, V, Mn, Zr, Nb, Ru, Mo, Ta, W, Si, and Al, in addition to Pt. The blending ratios can be variously varied within the above-mentioned ranges, while the characteristics as an effective magnetic recording medium being maintained. That is, these elements are optionally contained in the target for improving the characteristics as a magnetic recording medium. Among these elements, Cr may be contained in the target in an amount higher than those of the other elements.

The 20 mol % or less of Cr and/or 0.5 mol % or more and 10 mol % or less of at least one element selected from B, Ti, V, Mn, Zr, Nb, Ru, Mo, Ta, W, Si, and Al are basically present in the metal base (A), but may slightly disperse into the phase (B) of a Co—Pt alloy described below through the interface with the phase (B), which is encompassed in the present invention.

An important point of the present invention is that the structure of the target comprises a metal base (A) and a phase (B) of a Co—Pt alloy containing 40 to 76 mol % of Pt in the metal base (A). The phase (B) has a composition different from that of the metal base (A), has a maximum magnetic permeability lower than that of the metal base (A), and is separated from each other with the peripheral structure made of the metal base (A).

In the target having such a structure, the reasons of the improvement in leakage magnetic flux are not necessarily obvious at the present moment, however, it is believed that a high magnetic flux density portion as well as a low magnetic flux density portion are generated inside the target to cause an increase in magnetostatic energy compared with the structure having a uniform magnetic permeability and thereby leakage of the magnetic flux to the outside of the target is energetically advantageous.

The phase (B) can be spherical or flat (flake-like). The spherical phase (B) and the flat phase (B) each have advantages and disadvantages, and it is desirable to determine the shape of the phase (B) depending on the purpose of use of the target.

For example, the spherical phase (B) preferably has a diameter of 10 to 150 μm. The spherical phase (B) hardly causes formation of holes at the interface between the metal base (A) and the phase (B) when a target material is produced by sintering and can thereby increase the density of the target.

In addition, since the surface area of a spherical shape is the smallest when the volume is the same, diffusion of metal elements between the metal base (A) and the phase (B) hardly proceeds in sintering of the target material. As a result, a metal base (A) and a phase (B) of which compositions are different from each other are readily generated, and a target material having a phase of a Co—Pt alloy containing 40 to 76 mol % of Pt can be produced.

Though the spherical shape has an advantage to hardly allow progress of diffusion as described above, it does not mean that diffusion does not occur at all.

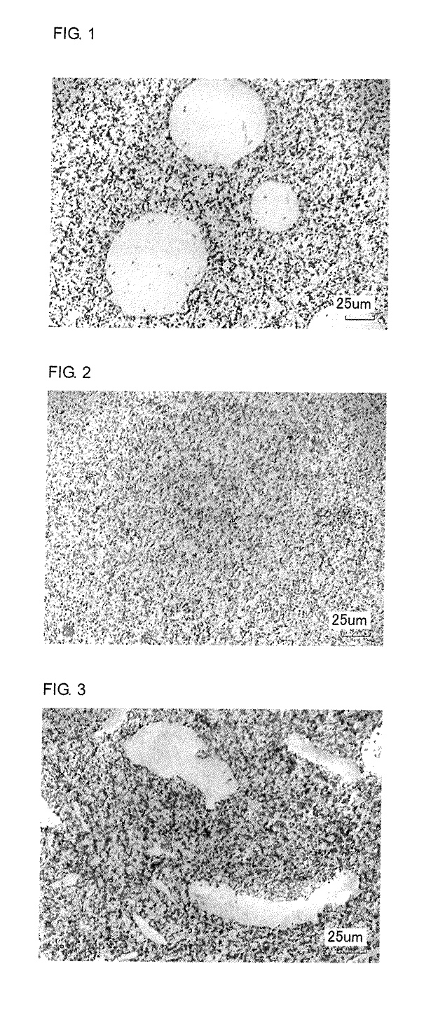

As shown in FIG. 1, the metal base (A) includes fine inorganic material particles, and the finely dispersed black portions in FIG. 1 are the inorganic material particles. If the diameter of the phase (B) is less than 10 μm, the difference in size between the inorganic material particles and the metal particles of the phase (B) is small to accelerate diffusion between the phase (B) and the metal base (A) during sintering of the target material.

The progress of the diffusion makes the difference in structural components between the metal base (A) and the phase (B) unclear. Hence, the diameter of the phase (B) is preferably 10 μm or more and desirably 30 μm or more.

If the diameter exceeds 150 μm, however, the smoothness of the target surface decreases with progress of sputtering to readily cause a problem of particles. Hence, the size of the phase (B) is preferably 10 to 150 μm and desirably 30 to 150 μm.

All of these regulations are for increasing the leakage magnetic flux. The leakage magnetic flux also can be controlled by the amounts and types or the like of metals and inorganic particles contained in a target. Thus, the above-described size of the phase (B) should not be necessarily satisfied, but obviously, is one of favorable conditions.

The term “spherical shape” used herein refers to three dimensional shapes including spheres, pseudo-spheres, spheroids (ellipsoids of revolution), and pseudo-spheroids. In every shape, the difference between the major axis and the minor axis is 0 to 50% based on the major axis. In other words, in the spherical shape, the ratio of the maximum to the minimum in the length from the center of gravity to the circumference is two or less. Within this range, the phase (B) can be formed even if the periphery has a few irregularities. When it is difficult to confirm the spherical shape itself, a ratio of the maximum to the minimum in the length from the center of gravity to the circumference of a cross section of the phase (B) being 2 or less may be used as a reference.

Even if the volume of the phase (B) based on the total volume of the target or the area of the phase (B) based on the erosion surface of the target is small (e.g., about 1%), the effect of a certain level can be obtained. In order to obtain a sufficient effect by the phase (B), however, the volume based on the total volume of the target or the area based on the erosion surface of the target is desirably 10% or more. A larger volume of the phase (B) can increase the leakage magnetic flux.

The volume of the phase (B) based on the total volume of the target or the area of the phase (B) based on the erosion surface of the target can be 50% or more, or further 60% or more, in some target compositions. These volume or area proportions can be appropriately adjusted depending on the composition of a target, which is encompassed in the present invention.

When the phase (B) is flat, however, detachment of the phase (B) from the peripheral metal base (A) during sputtering can be prevented by the effect of the phase as a wedge.

In the flat phase (B), variation in erosion rate, which tends to occur in the spherical phase by destruction of the spherical shape, can be reduced to prevent occurrence of particles which is caused by interfaces having different erosion rates.

The flat phase (B) refers to those having shapes such as a wedge, a crescent-like shape, a semicircle, or a combination of two or more thereof.

In quantitative regulation of these shapes, the flat shape is defined to have a ratio of the minor axis to the major axis (hereinafter, referred to as aspect ratio) of 1:2 to 1:10 in average. The flat shape is that viewed from above and does not refer to a completely flat shape without irregularities. That is, the shape includes those having a few undulations or irregularities.

The phase (B) in a flat shape preferably has an average particle diameter of 10 μm or more and 150 μm or less, desirably 15 μm or more and 150 μm or less. The lower limit of the preferred average particle diameter in this case is slightly different from that in the spherical shape. And a slightly larger particle diameter is desirable with a flat phase; this is because a flat phase tends to diffuse compared with a spherical phase.

As shown in FIG. 1, the metal base (A) includes the phase (B) and fine inorganic material particles (in FIG. 1, the finely dispersing black portions are the inorganic material particles, and the relatively large circular portions are the phase (B)). If the diameter of the phase (B) is less than 10 μm, the difference in size of the inorganic material particles and the metal particles of the phase (B) is small to accelerate diffusion between the phase (B) and the metal base (A) during sintering of the target material.

The progress of the diffusion makes the difference in structural components between the metal base (A) and the phase (B) unclear. Thus, the diameter of the phase (B) is preferably 10 μm or more, more preferably 15 μm or more, and most preferably 30 μm or more.

Meanwhile, if the diameter exceeds 150 μm, the smoothness of the target surface is lost as sputtering process advances to readily cause a problem of particles.

Thus, the size of the phase (B) is 10 μm or more and 150 μm or less, more preferably 15 μm or more and 150 μm or less, and most preferably 30 μm or more and 150 μm or less.

As described above, the phase (B) of the present invention is made of a Co—Pt alloy containing 40 to 76 mol % of Pt. Since the phase (B), irrespective of spherical or flat, has a composition different from that of the metal base (A), the composition in the periphery of the phase (B) may slightly change from that of the phase (B) by diffusion of elements during sintering.

Within the range of a phase having a shape similar to that of the phase (B) when the diameters (major axis and minor axis) of the phase (B) are each reduced to ⅔ thereof, if the phase (B) is made of a Co—Pt alloy having 40 to 76 mol % of Pt, the purpose can be achieved. The present invention encompasses these cases and can achieve the purpose under such conditions.

Furthermore, the ferromagnetic material sputtering target of the present invention may contain at least one inorganic material selected from carbon, oxides, nitrides, carbides, and carbonitrides in a dispersed state in the metal base. In such a case, the target has characteristics suitable as a material for a magnetic recording film having a granular structure, in particular, a recording film for a hard disk drive employing a perpendicular magnetic recording system.

Furthermore, as the inorganic material, at least one oxide of an element selected from Cr, Ta, Si, Ti, Zr, Al, Nb, B, and Co is effective. The volume proportion of the inorganic material can be 22 to 40 vol %. In the above case of an oxide of Cr, the amount of Cr of the oxide is distinguished from the amount of Cr added as a metal and is determined as a volume proportion as a chromium oxide.

Though the nonmagnetic material particles are basically dispersed in the metal base (A), some of the magnetic material particles adhere to the circumference of the phase (B) or are contained inside the phase (B) during producing a target. The nonmagnetic material particles in such a case, if the amount is small, do not affect the magnetic characteristics of the phase (B) and do not inhibit the purpose.

The ferromagnetic material sputtering target of the present invention desirably has a relative density of 97% or more. It is generally known that a target having a higher density can reduce the amount of particles occurring during sputtering. In the present invention also, similarly, a higher density of the ferromagnetic material sputtering target is preferred, and the present invention can achieve the above-mentioned relative density.

The relative density herein is a value determined by dividing the measured density of a target by the calculated density (theoretical density). The calculated density is a density when it is assumed that the structural components of a target do not diffuse to or do not react with each other and is calculated by the following on:

calculated density=Σ[(molecular weight of a structural component)×(molar ratio of the structural component)]/Σ[(molecular weight of the structural component)×(molar ratio of the structural component)/(literature density data of the structural component)], Expression:

wherein, Σ means the sum of all structural components.

The thus prepared target provides a large leakage magnetic flux. When the target is used in a magnetron sputtering device, ionization of an inert gas is efficiently accelerated to give stable discharge. Increase of the thickness of the target enables a reduction in frequency of replacement of the target, which results in an advantage that a magnetic thin film can be produced with low cost.

Furthermore, the high density can advantageously reduce occurrence of particles that cause a reduction in yield.

The ferromagnetic material sputtering target of the present invention can be produced by a powder metallurgy process. First, a powder of a metal element or alloy is prepared; here, note that a Co—Pt alloy powder is indispensable for forming the phase (B). As needed, an optional metal element powder to be added or inorganic material powder is prepared.

Each metal element powder may be produced by any method. The maximum particle diameters of these powders are each desirably 20 μm or less. While, the diameter is desirably 0.1 μm or more since too small a particle diameter accelerates oxidation to cause problems such that the component composition is outside the necessary range.

Subsequently, the metal powder and the alloy powder are weighed to achieve a desirable composition and are mixed and pulverized with a known procedure with a ball mill, for example. When an inorganic material powder is also added, it may be mixed with the metal powder and the alloy powder in this stage.

The inorganic material powder is a carbon powder, an oxide powder, a nitride powder, a carbide powder, or a carbonitride powder and desirably has a maximum particle diameter of 5 μm or less. While, the diameter is more desirably 0.1 μm or more since too small a particle diameter tends to cause aggregation.

In formation of a spherical phase (B), for example, a spherical powder of Co-45 mol % Pt having a diameter in the range of 30 to 150 μm and a metal powder (and an optionally selected inorganic material powder) prepared in advance are mixed with a mixer. The Co—Pt spherical powder can be prepared by gas atomization and sieving the resulting powder. The mixer is preferably a planetary-screw mixer or planetary-screw agitator. In addition, considering the problem of oxidation during mixing, the mixing is preferably performed in an inert gas atmosphere or in vacuum.

In formation of a flat (flake-like) phase (B), for example, a spherical powder of Co-45 mol % Pt having a diameter in the range of 50 to 300 μm is prepared and pulverized with a high-energy ball mill. The Co—Pt powder becomes into a flat shape with progress of pulverization. The pulverization is continued to give a particle diameter of 150 μm or less. The Co—Pt spherical powder used here can be prepared by the gas atomization method and sieving the resulting powder.

The high energy ball mill can pulverize and mix raw material powders within a short time compared with a ball mill or a vibration mill. Subsequently, the flat Co—Pt powder is mixed with a mixture of a metal powder and an optionally selected inorganic material powder prepared in advance with a mixer. The mixer is preferably a planetary-screw mixer or planetary movement agitator. In addition, considering the problem of oxidation during mixing, the mixing is preferably performed in an inert gas atmosphere or in vacuum.

Alternatively, a Co—Pt spherical powder having a diameter in the range of 50 to 300 μm and a metal powder (and an optionally selected inorganic material powder) prepared in advance may be pulverized and mixed with a high-energy ball mill. In this case, the Co—Pt powder becomes a flat shape with progress of pulverization. The pulverization and mixing are continued to give a particle diameter of 150 μm or less. In addition, considering the problem of oxidation of metal components during mixing, the mixing is preferably performed in an inert gas atmosphere or in vacuum.

The thus prepared powder is molded and sintered with a vacuum hot press device, followed by machining into a intended shape to provide a ferromagnetic material sputtering target of the present invention. The Co—Pt spherical powder or the Co—Pt flat powder formed through the pulverization corresponds to the spherical phase (B) that is observed in the target structure.

The molding and sintering is not limited to hot press, but may be performed by plasma discharge sintering or hot isostatic sintering. The retention temperature for the sintering is preferably set to the lowest in the temperature range in which the target is sufficiently densified. Though it depends on the composition of a target, in many cases, the temperature is in the range of 800 to 1300° C. The pressure in the sintering is preferably 300 to 500 kg/cm².

### EXAMPLES

The present invention will be described by Examples and Comparative Examples below. The Examples are merely illustrative, and the present invention shall in no way be limited thereby. In other words, the present invention shall only be limited by the scope of claims for a patent, and shall include the various modifications other than the Examples of this invention.

### Example 1 and Comparative Example 1

In Example 1, a Co powder having an average particle diameter of 3 μm, a Pt powder having an average particle diameter of 3 μm, a SiO₂ powder having an average particle diameter of 1 μm, and a Co-45Pt (mol %) spherical powder having a diameter in the range of 50 to 100 μm were prepared as raw material powders. These powders were weighed at weight proportions of 40.08 wt % of the Co powder, 13.06 wt % of the Pt powder, 4.96 wt % of the SiO₂ powder, and 41.91 wt % of the Co—Pt spherical powder to give a target having a composition of 74Co-19Pt-7SiO₂ (mol %).

Subsequently, the Co powder, the Pt powder, and the SiO₂ powder were placed in a 10-liter ball mill pot together with zirconia balls as pulverizing media, and the mill pot was sealed and rotated for 20 hours for mixing. The resulting powder mixture was further mixed with the Co—Pt spherical powder with a planetary movement mixer having a ball capacity of about 7 liters for 10 minutes.

The powder mixture was filled up in a carbon mold and was hot-pressed in a vacuum atmosphere under conditions of a temperature of 1100° C., a retention time of 2 hours, and a pressure of 30 MPa to obtain a sintered compact. The sintered compact was ground with a surface grinder to give a disk-shaped target having a diameter of 180 mm and a thickness of 5 mm.

The leakage magnetic flux was measured with reference to ASTM F2086-01 (Standard Test Method for Pass Through Flux of Circular Magnetic Sputtering Targets, Method 2). The target was fixed at the center thereof and was rotated by 0, 30, 60, 90, and 120 degrees, and the leakage magnetic flux density of the target was measured at each degree and was divided by the reference field value defined by ASTM and multiplied by 100 to give a percent value. The average value of the five points is shown in Table 1 as the average leakage magnetic flux density (PTF (%)).

In Comparative Example 1, a Co powder having an average particle diameter of 3 μm, a Pt powder having an average particle diameter of 3 μm, and a SiO₂ powder having an average particle diameter of 1 μm were prepared as raw material powders. These powders were weighed at weight proportions of 51.38 wt % of the Co powder, 43.67 wt % of the Pt powder, and 4.96 wt % of the SiO₂ powder to give a target having a composition of 74Co-19Pt-7SiO₂ (mol %).

These powders were placed in a 10-liter ball mill pot together with zirconia balls as pulverizing media, and the mill pot was sealed and rotated for 20 hours for mixing.

Subsequently, the resulting powder mixture was filled up in a carbon mold and was hot-pressed in a vacuum atmosphere under conditions of a temperature of 1100° C., a retention time of 2 hours, and a pressure of 30 MPa to obtain a sintered compact. The sintered compact was ground with a surface grinder to give a disk-shaped target having a diameter of 180 mm and a thickness of 5 mm. The average leakage magnetic flux density of the target was measured. The result is shown in Table 1.

TABLE 1

| | | | | Relative |
|---|---|---|---|---|
| No. | Target composition (mol %) | Phase (B) | PTF(%) | density (%) |
| Example 1 | 74Co—19Pt—7SiO₂ | particle size: 50 to 100 μm, | 41.5 | 97.4 |
| | | spherical, Co-45 mol % Pt | | |
| Comparative | 74Co—19Pt—7SiO₂ | None | 39.1 | 97.2 |
| Example 1 | | | | |

As shown in Table 1, the average leakage magnetic flux density of the target of Example 1 was 41.5%, which was larger than that, 39.1%, of Comparative Example 1, and was confirmed to be considerably improved. In Example 1, the relative density was 97.4%. Thus, a target having a high density of exceeding 97% was provided.

FIG. 1 shows a structural image of the polished surface of the target of Example 1 observed under an optical microscope. In FIG. 1, the blackish portions correspond to SiO₂ particles. As shown in the structural image of FIG. 1, a notable characteristic in Example 1 is that the large spherical phase not containing SiO₂ particles is dispersed in a matrix in which SiO₂ particles are finely dispersed.

This phase is the phase (B) of the present invention, is made of a Co—Pt alloy containing 45 mol % of Pt, and has an approximately spherical shape where the ratio of the maximum to the minimum in the length from the center of gravity to the circumference is about 1.2.

In contrast, in the structural image of the polished surface of the target prepared in Comparative Example 1 shown in FIG. 2, no spherical phase was observed at all in the matrix in which SiO₂ particles are dispersed.

### Example 2 and Comparative Examples 2 to 4

In Example 2, a Co powder having an average particle diameter of 3 μm, a Cr powder having an average particle diameter of 5 μm, a TiO₂ powder having an average particle diameter of 1 μm, a SiO₂ powder having an average particle diameter of 1 μm, a Cr₂O₃ powder having an average particle diameter of 3 μm, and a Co-53Pt (mol %) spherical powder having a diameter in the range of 50 to 100 μm were prepared as raw material powders.

These powders were weighed at weight proportions of 26.53 wt % of the Co powder, 6.38 wt % of the Cr powder, 4.45 wt % of the TiO₂ powder, 1.34 wt % of the SiO₂ powder, 3.39 wt % of the Cr₂O₃ powder, and 57.91 wt % of the Co—Pt spherical powder to give a target having a composition of 59Co-11Cr-21Pt-5TiO₂-2SiO₂-2Cr₂O₃ (mol %).

Subsequently, the Co powder, the Cr powder, the TiO₂ powder, the SiO₂ powder, and the Cr₂O₃ powder were placed in a 10-liter ball mill pot together with zirconia balls as pulverizing media, and the mill pot was sealed and rotated for 20 hours for mixing. The resulting powder mixture and the Co—Pt spherical powder were placed in a high energy ball mill and were pulverized and mixed for 2 hours.

The powder mixture was filled up in a carbon mold and was hot-pressed in a vacuum atmosphere under conditions of a temperature of 1050° C., a retention time of 2 hours, and a pressure of 30 MPa to obtain a sintered compact. The sintered compact was ground with a surface grinder to give a disk-shaped target having a diameter of 180 mm and a thickness of 5 mm. The average leakage magnetic flux density of the target was measured. The result is shown in Table 2.

In Comparative Example 2, a Co powder having an average particle diameter of 3 μm, a Cr powder having an average particle diameter of 5 μm, a TiO₂ powder having an average particle diameter of 1 μm, a SiO₂ powder having an average particle diameter of 1 μm, a Cr₂O₃ powder having an average particle diameter of 3 μm, and a Co-37Pt (mol %) spherical powder having a diameter in the range of 50 to 100 μm were prepared as raw material powders.

These powders were weighed at weight proportions of 15.27 wt % of the Co powder, 6.38 wt % of the Cr powder, 4.45 wt % of the TiO₂ powder, 1.34 wt % of the SiO₂ powder, 3.39 wt % of the Cr₂O₃ powder, and 69.17 wt % of the Co—Pt spherical powder to give a target having a composition of 59Co-11Cr-21Pt-5TiO₂-2SiO₂-2Cr₂O₃ (mol %).

Subsequently, the Co powder, the Cr powder, the TiO₂ powder, the SiO₂ powder, and the Cr₂O₃ powder were placed in a 10-liter ball mill pot together with zirconia balls as pulverizing media, and the mill pot was sealed and rotated for 20 hours for mixing. The resulting powder mixture and the Co—Pt spherical powder were placed in a high energy ball mill and were pulverized and mixed for 2 hours.

The powder mixture was filled up in a carbon mold and was hot-pressed in a vacuum atmosphere under conditions of a temperature of 1050° C., a retention time of 2 hours, and a pressure of 30 MPa to obtain a sintered compact. The sintered compact was ground with a surface grinder to give a disk-shaped target having a diameter of 180 mm and a thickness of 5 mm. The average leakage magnetic flux density of the target was measured. The result is shown in Table 2.

In Comparative Example 3, a Co powder having an average particle diameter of 3 μm, a Cr powder having an average particle diameter of 5 μm, a TiO₂ powder having an average particle diameter of 1 μm, a SiO₂ powder having an average particle diameter of 1 μm, a Cr₂O₃ powder having an average particle diameter of 3 μm, and a Co-79Pt (mol %) spherical powder having a diameter in the range of 50 to 100 μm were prepared as raw material powders.

These powders were weighed at weight proportions of 35.10 wt % of the Co powder, 6.38 wt % of the Cr powder, 4.45 wt % of the TiO₂ powder, 1.34 wt % of the SiO₂ powder, 3.39 wt % of the Cr₂O₃ powder, and 49.34 wt % of the Co—Pt spherical powder to give a target having a composition of 59Co-11Cr-21Pt-5TiO₂-2SiO₂-2Cr₂O₃ (mol %).

Subsequently, the Co powder, the Cr powder, the TiO₂ powder, the SiO₂ powder, and the Cr₂O₃ powder were placed in a 10-liter ball mill pot together with zirconia balls as pulverizing media, and the mill pot was sealed and rotated for 20 hours for mixing. The resulting powder mixture and the Co—Pt spherical powder were placed in a high energy ball mill and were pulverized and mixed for 2 hours.

The powder mixture was filled up in a carbon mold and was hot-pressed in a vacuum atmosphere under conditions of a temperature of 1050° C., a retention time of 2 hours, and a pressure of 30 MPa to obtain a sintered compact. The sintered compact was ground with a surface grinder to give a disk-shaped target having a diameter of 180 mm and a thickness of 5 mm. The average leakage magnetic flux density of the target was measured. The result is shown in Table 2.

In Comparative Example 4, a Co powder having an average particle diameter of 3 μm, a Cr powder having an average particle diameter of 5 μm, a Pt powder having an average particle diameter of 3 μm, a TiO₂ powder having an average particle diameter of 1 μm, a SiO₂ powder having an average particle diameter of 1 μm, and a Cr₂O₃ powder having an average particle diameter of 3 μm were prepared as raw material powders.

These powders were weighed at weight proportions of 38.77 wt % of the Co powder, 6.38 wt % of the Cr powder, 45.67 wt % of the Pt powder, 4.45 wt % of the TiO₂ powder, 1.34 wt % of the SiO₂ powder, and 3.39 wt % of the Cr₂O₃ powder to give a target having a composition of 59Co-11Cr-21 Pt-5TiO₂-2SiO₂-2Cr₂O₃ (mol %).

Subsequently, the Co powder, the Cr powder, the Pt powder, the TiO₂ powder, the SiO₂ powder, and the Cr₂O₃ powder were placed in a 10-liter ball mill pot together with zirconia balls as pulverizing media, and the mill pot was sealed and rotated for 20 hours for mixing. The resulting powder mixture was placed in a high energy ball mill and was pulverized and mixed for 2 hours.

The powder mixture was filled up in a carbon mold and was hot-pressed in a vacuum atmosphere under conditions of a temperature of 1050° C., a retention time of 2 hours, and a pressure of 30 MPa to obtain a sintered compact. The sintered compact was ground with a surface grinder to give a disk-shaped target having a diameter of 180 mm and a thickness of 5 mm. The average leakage magnetic flux density of the target was measured. The result is shown in Table 2.

TABLE 2

| | | | | Relative |
|---|---|---|---|---|
| No. | Target composition (mol %) | Phase (B) | PTF(%) | density (%) |
| Example 2 | 59Co—11Cr—21Pt—5TiO₂—2SiO₂—2Cr₂O₃ | particle size: 50 to 100 μm, | 52.2 | 98.5 |
| | | flat, Co-53 mol % Pt | | |
| Comparative | 59Co—11Cr—21Pt—5TiO₂—2SiO₂—2Cr₂O₃ | particle size: 50 to 100 μm, | 46.7 | 98.0 |
| Example 2 | | flat, Co-37 mol % Pt | | |
| Comparative | 59Co—11Cr—21Pt—5TiO₂—2SiO₂—2Cr₂O₃ | particle size: 50 to 100 μm, | 46.0 | 98.4 |
| Example 3 | | flat, Co-79 mol % Pt | | |
| Comparative | 59Co—11Cr—21Pt—5TiO₂—2SiO₂—2Cr₂O₃ | None | 45.7 | 98.6 |
| Example 4 | | | | |

As shown in Table 2, the average leakage magnetic flux density of the target of Example 2 was 52.2%, which was larger than those, 46.7%, 46.0%, and 45.7%, of Comparative Examples 2 to 4, and was confirmed to be considerably improved. In Example 2, the relative density was 98.5%. Thus, a target having a high density of exceeding 98% was provided.

FIG. 3 shows a structural image of the polished surface of the target of Example 2 observed under an optical microscope. In FIG. 3, the blackish portions correspond to TiO₂ particles, SiO₂ particles, and Cr₂O₃ particles. As shown in the structural image of FIG. 3, a notable characteristic in the above Example 2 is that the large flat phase not containing TiO₂ particles, SiO₂ particles, and Cr₂O₃ particles is dispersed in a matrix in which TiO₂ particles, SiO₂ particles, and Cr₂O₃ particles are finely dispersed. This phase is the phase (B) of the present invention, is made of a Co—Pt alloy containing 53 mol % of Pt, and has a flat shape where the ratios of the minor axis to the major axis at arbitrary five points are about 1:5 to 1:10.

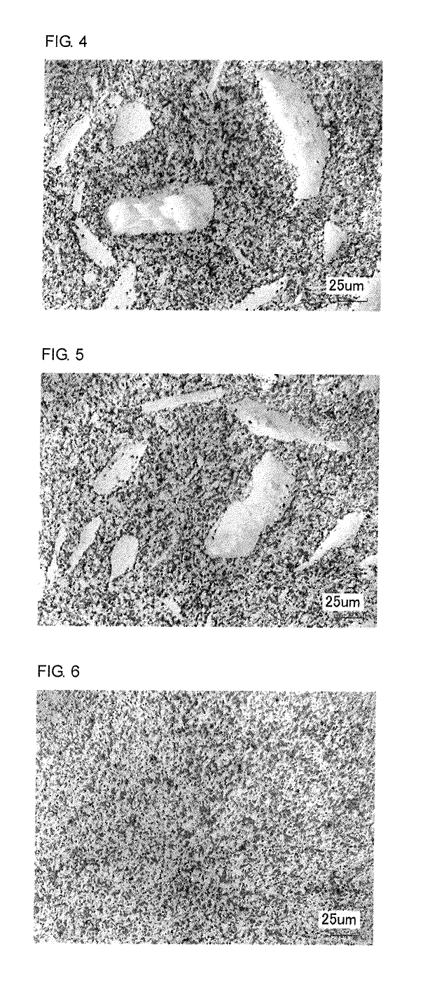

In contrast, in the polished surface of the target prepared in Comparative Example 2 shown in FIG. 4, though a flat phase was observed, it was a phase made of a Co—Pt alloy containing 37 mol % of Pt, and the average leakage magnetic flux density was not highly improved.

In the polished surface of the target prepared in Comparative Example 3 shown in FIG. 5, though a flat phase was observed, it was a phase made of a Co—Pt alloy containing 79 mol % of Pt, and the average leakage magnetic flux density was not highly improved.

In the structural image of the polished surface of the target prepared in Comparative Example 4 shown in FIG. 6, no flat phase was observed at all.

In both Examples 1 and 2, a metal base (A) and a phase (B) having a diameter of 50 to 100 μm (see the photographs of the structures) surrounded by the metal base (A) were confirmed. In addition, it was confirmed that the phase (B) was a phase of a Co—Pt alloy containing 40 to 76 mol % of Pt. It was revealed that such a structural constitution plays a very important role for improving the leakage magnetic flux.

The above-mentioned Examples are an example of a target having a composition of 74Co-19Pt-7SiO₂ (mol %) and an example of a target having a composition of 59Co-11Cr-21Pt-5TiO₂-2SiO₂-2Cr₂O₃ (mol %). It was confirmed that similar effects can be obtained when the composition ratio is changed within the range of the present invention.

The target may contain at least one element selected from B, Ti, V, Mn, Zr, Nb, Ru, Mo, Ta, W, Si, and Al, and all of such targets can maintain the characteristics as effective magnetic recording media. In other words, these elements are elements that are optionally added to targets for improving the characteristics as magnetic recording media. The effects are not specifically shown in Examples, however, it was confirmed that the effects were equivalent to those shown in Examples of the present invention.

Further, the above-described Examples show examples in which oxides of Cr, Si, or Ti are added, but equivalent effects are shown in case of other oxides as Ta, Zr, Al, Nb, B, or Co. In addition, though Examples show the cases of using oxides of these elements, it was confirmed that nitrides, carbides, and carbonitrides of these elements and further carbon can show effects equivalent to those of oxides.

The present invention regulates the structural constitution of a ferromagnetic material sputtering target to allow improvement dramatically in leakage magnetic flux. Accordingly, the use of a target of the present invention can give stable discharge in sputtering with a magnetron sputtering device. Furthermore, it is possible to increase the thickness of a target, and thereby the target lifetime becomes long to allow production of a magnetic material thin film at a low cost.

The target of the present invention is useful as a ferromagnetic material sputtering target that is used for forming a magnetic material thin film of a magnetic recording medium, in particular, forming a film of a hard disk drive recording layer.

1. A ferromagnetic material sputtering target having a metal composition comprising 5 mol % or more of Pt and the balance of Co, wherein the target has a structure including a metal base (A) and a phase (B) of a Co—Pt alloy containing 40 to 76 mol % of Pt in the metal base (A), and the phase (B) has a particle diameter of 10 μm or more and 150 μm or less.

2. A ferromagnetic material sputtering target having a metal composition comprising 5 mol % or more of Pt, 20 mol % or less of Cr, and the balance of Co, wherein the target has a structure including a metal base (A) and a phase (B) of a Co—Pt alloy containing 40 to 76 mol % of Pt in the metal base (A), and the phase (B) has a particle diameter of 10 μm or more and 150 μm or less.

3. The ferromagnetic material sputtering target according to claim 2, further comprising 0.5 mol % or more and 10 mol % or less of at least one element selected from B, Ti, V, Mn, Zr, Nb, Ru, Mo, Ta, W, Si, and Al as additional elements.

4. The ferromagnetic material sputtering target according to claim 3, wherein the metal base (A) contains at least one inorganic material component selected from carbon, oxides, nitrides, carbides, and carbonitrides in the metal base.

5. The ferromagnetic material sputtering target according to claim 4, wherein the inorganic material is at least one oxide of an element selected from Cr, Ta, Si, Ti, Zr, Al, Nb, B, and Co; and the volume proportion of the inorganic material is 22 to 40 vol %.

6. (canceled)

7. The ferromagnetic material sputtering target according to claim 5, having a relative density of 97% or more.

8. The ferromagnetic material sputtering target according to claim 2, wherein the metal base (A) contains at least one inorganic material component selected from carbon, oxides, nitrides, carbides, and carbonitrides in the metal base.

9. The ferromagnetic material sputtering target according to claim 8, wherein the inorganic material is at least one oxide of an element selected from Cr, Ta, Si, Ti, Zr, Al, Nb, B, and Co, and the volume proportion of the inorganic material is 22 to 40 vol %.

10. The ferromagnetic material sputtering target according to claim 2, wherein the target has a relative density of 97% or more.

11. The ferromagnetic material sputtering target according to claim 1, further comprising 0.5 to 10 mol % of at least one element selected from B, Ti, V, Mn, Zr, Nb, Ru, Mo, Ta, W, Si, and Al.

12. The ferromagnetic material sputtering target according to claim 11, wherein the metal base (A) contains at least one inorganic material component selected from carbon, oxides, nitrides, carbides, and carbonitrides in the metal base.

13. The ferromagnetic material sputtering target according to claim 12, wherein the inorganic material is at least one oxide of an element selected from Cr, Ta, Si, Ti, Zr, Al, Nb, B, and Co, and the volume proportion of the inorganic material is 22 to 40 vol %.

14. The ferromagnetic material sputtering target according to claim 13, wherein the target has a relative density of 97% or more.

15. The ferromagnetic material sputtering target according to claim 1, wherein the metal base (A) contains at least one inorganic material component selected from carbon, oxides, nitrides, carbides, and carbonitrides in the metal base.

16. The ferromagnetic material sputtering target according to claim 15, wherein the inorganic material is at least one oxide of an element selected from Cr, Ta, Si, Ti, Zr, Al, Nb, B, and Co, and the volume proportion of the inorganic material is 22 to 40 vol %.

17. The ferromagnetic material sputtering target according to claim 1, wherein the target has a relative density of 97% or more.
